(19) United States
(12) Patent Application Publication
(10) Pub. No.: US 2023/0301060 A1
(43) Pub. Date: Sep. 21, 2023

(54) THREE-DIMENSIONAL SILICON NANOSHEET MEMORY WITH METAL CAPACITOR

(71) Applicant: Tokyo Electron Limited, Tokyo (JP)

(72) Inventors: H. Jim FULFORD, Marianna, FL (US); Mark I. GARDNER, Cedar Creek, TX (US); Partha MUKHOPADHYAY, Oviedo, FL (US)

(73) Assignee: Tokyo Electron Limited, Tokyo (JP)

(21) Appl. No.: 17/971,219

(22) Filed: Oct. 21, 2022

Related U.S. Application Data
(60) Provisional application No. 63/320,471, filed on Mar. 16, 2022.

(51) Int. Cl. H01L 27/108

(52) U.S. Cl. CPC H01L 27/10805; H01L 27/1085; H01L 27/10873

(57) ABSTRACT

Aspects of the present disclosure provide a semiconductor structure. For example, the semiconductor structure can include a lower transistor including a lower channel that is elongated horizontally, and an upper transistor vertically stacked over the lower transistor and including an upper channel that is elongated horizontally. The semiconductor structure can also include a lower metal capacitor electrically connected to and horizontally elongated from the lower transistor. The lower metal capacitor can include a first lower metal plate that is in-plane with the lower channel of the lower transistor. The semiconductor structure can also include an upper metal capacitor vertically stacked over the lower metal capacitor and electrically connected to and horizontally elongated from the upper transistor. The upper metal capacitor can include a first upper metal plate that is in-plane with the upper channel of the upper transistor.

[symbol]

method for improving overlay alignment of patterning by correcting wafer shape. For example, the method can include receiving a wafer having

[symbol]

### INCORPORATION BY REFERENCE

This present disclosure claims the benefit of U.S. Provisional Application No. 63/320,471, “3D SILICON NANOSHEET MEMORY WITH METAL CAPACITOR” filed on Mar. 16, 2022, which is incorporated herein by reference in its entirety.

### FIELD OF THE INVENTION

This disclosure relates to microelectronic devices including semiconductor devices, transistors, and integrated circuits, including methods of microfabrication.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

Aspects of the present disclosure provide a method for fabricating a semiconductor structure. For example, the method can include forming over a substrate a lower stack of alternating metal and dielectric layers that are parallel to a top surface of the substrate. The method can also include forming an upper stack of alternating metal and dielectric layers that are parallel to the top surface of the substrate. The upper stack can be vertically stacked over the lower stack. The method can also include forming a first opening through the upper stack and the lower stack until uncovering a top surface of the substrate, and forming within the first opening a lower transistor that is insulated from the substrate and an upper transistor that is vertically stacked over the lower transistor. The lower transistor can include a lower channel that is elongated horizontally and be in-plane with a first lower metal layer of the lower stack. The lower transistor can be electrically connected to a lower metal capacitor that includes the first lower metal layer as a first lower metal plate and a second lower metal layer of the lower stack as a second lower metal plate. The upper transistor can include an upper channel that is elongated horizontally and be in-plane with a first upper metal layer of the upper stack. The upper transistor can be electrically connected to an upper metal capacitor that includes the first upper metal layer as a first upper metal plate and a second upper metal layer of the upper stack as a second upper metal plate.

In an embodiment, the method can further include forming a second opening through the upper stack and the lower stack until uncovering at least a portion of the second lower metal layer of the lower stack, recessing a portion of the first lower metal layer of the lower stack and the first upper metal layer of the upper stack that is uncovered by the second opening and replacing with an insulating material, and filing the second opening with a first metal material to electrically connect the second lower metal layer of the lower stack and the second upper metal layer of the upper stack.

In an embodiment, the lower transistor can further include a lower gate region that surrounds the lower channel, and the upper transistor can further include an upper gate region that surrounds the upper channel. For example, the upper gate region can be electrically connected to the lower gate region. In an embodiment, the lower transistor and the upper transistor can be formed by epitaxially growing a first single crystal material on the substrate within the first opening, and epitaxially growing a second single crystal material over the first single crystal material to maintain single crystallinity. The second single crystal material can be etched selectively with respect to the first single crystal material. The lower transistor and the upper transistor can be formed further by epitaxially growing the lower channel of the lower transistor over the second single crystal material. The lower channel can cover a lateral side of the first lower metal layer of the lower stack. The lower transistor and the upper transistor can be formed further by epitaxially growing a third single crystal material over the lower channel. The third single crystal material can be etched selectively with respect to the first single crystal material. The lower transistor and the upper transistor can be formed further by epitaxially growing the upper channel of the upper transistor over the third single crystal material. The upper channel can cover a lateral side of the first upper metal layer of the upper stack. The lower transistor and the upper transistor can be formed further by epitaxially growing a fourth single crystal material over the upper channel. The fourth single crystal material can be etched selectively with respect to the first single crystal material. The lower transistor and the upper transistor can be formed further by etching and removing the first single crystal material and replacing with an insulating material. The lower transistor and the upper transistor can be formed further by etching the second single crystal material, the third single crystal material and the fourth single crystal material to uncover the lower channel and the upper channel, forming the lower gate region and the upper gate region that surround the lower channel and the upper channel, respectively, and filling the first opening with a second metal material. In another embodiment, the method can further include recessing within the first opening a portion of a second lower metal layer of the lower stack and a second upper metal layer of the upper stack that are stacked over the first lower metal layer and the first upper metal layer, respectively, and replacing with an insulating material.

In an embodiment, the second single crystal material, the third single crystal material and the fourth crystal material can be the same. For example, the second single crystal material can include SiGe30. In another embodiment, the first single crystal material can include SiGe90.

In an embodiment, the method can further include annealing the lower channel to develop a first silicide at two ends thereof, and annealing the upper channel to develop a second silicide at two ends thereof.

In an embodiment, the lower metal capacitor can further include a lower dielectric layer of the lower stack that is between to the first lower metal plate and the second lower metal plate and is in-plane with the lower gate region of the lower transistor, and the upper metal capacitor can further include an upper dielectric layer of the upper stack that is between the first upper metal plate and the second upper metal plate and is in-plane with the upper gate region of the upper transistor. In another embodiment, the lower transistor can be narrower than the lower metal capacitor horizontally.

Aspects of the present disclosure also provide a semiconductor structure. For example, the semiconductor structure can include a lower transistor including a lower channel that is elongated horizontally, and an upper transistor vertically stacked over the lower transistor and including an upper channel that is elongated horizontally. The semiconductor structure can also include a lower metal capacitor electrically connected to and horizontally elongated from the lower transistor. The lower metal capacitor can include a first lower metal plate that is in-plane with the lower channel of the lower transistor. The semiconductor structure can also include an upper metal capacitor vertically stacked over the lower metal capacitor and electrically connected to and horizontally elongated from the upper transistor. The upper metal capacitor can include a first upper metal plate that is in-plane with the upper channel of the upper transistor.

In an embodiment, the lower metal capacitor can further include a second lower metal plate that is parallel to and insulated from the first lower metal plate, and the upper metal capacitor can further include a second upper metal plate that is parallel to and insulated from the first upper metal plate. For example, the second upper metal plate can be electrically connected to the second lower metal plate. In another embodiment, the lower transistor can further include a lower gate region that surrounds the lower channel and the upper transistor can further include an upper gate region that surrounds the upper channel. For example, the upper gate region can be electrically connected to the lower gate region.

In an embodiment, the lower metal capacitor can further include a lower dielectric layer that is parallel to the first lower metal plate and in-plane with the lower gate region of the lower transistor, and the upper metal capacitor can further include an upper dielectric layer that is parallel to the first upper metal plate and in-plane with the upper gate region of the upper transistor.

In an embodiment, the lower transistor can be narrower than the lower metal capacitor horizontally. In another embodiment, the semiconductor structure can further include a first silicide formed on two ends of the lower channel of the lower transistor, and a second silicide formed on two ends of the upper channel of the upper transistor.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the present disclosure and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A-23A show schematic views of various intermediary steps of a first exemplary method for fabricating a semiconductor structure according to the some embodiments of the present disclosure;

FIGS. 1B-23B show cross-sectional views of the semiconductor structure along cut lines BB′ shown in FIGS. 1A-23A, respectively, according to the some embodiments of the present disclosure;

FIGS. 3C, 5C and 23C show cross-sectional views of the semiconductor structure along cut lines CC′ shown in FIGS. 3A, 5A and 23A, respectively, according to the some embodiments of the present disclosure;

FIGS. 5D, 9C-19C and 23D show cross-sectional views of the semiconductor structure along cut lines DD′ shown in FIGS. 5A, 9A-19A and 23A, respectively, according to the some embodiments of the present disclosure;

FIGS. 24A-37A show schematic views of various intermediary steps of a second exemplary method for fabricating a semiconductor structure according to the some embodiments of the present disclosure;

FIGS. 24B-37B show cross-sectional views of the semiconductor structure along cut lines BB′ shown in FIGS. 24A-37A, respectively, according to the some embodiments of the present disclosure;

FIG. 37C shows a cross-sectional view of the semiconductor structure along a cut line CC′ shown in FIG. 37A according to the some embodiments of the present disclosure; and

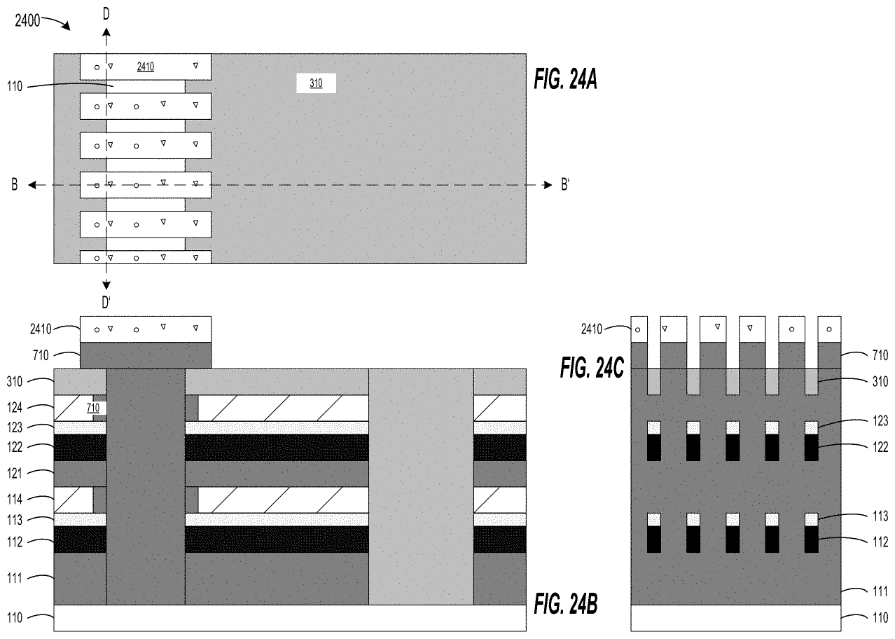

FIGS. 24C-36C and 37D show cross-sectional views of the semiconductor structure 2400 along cut lines DD′ shown in FIGS. 24A-37A, respectively, according to the some embodiments of the present disclosure.

### DETAILED DESCRIPTION

Three-dimensional (3D) integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips, e.g., central processing units (CPUs), graphics processing units (GPUs), field programmable gate arrays (FPGAs) and system on a chip (SoC), is being pursued.

Techniques herein include methods and designs for horizontal dynamic random access memory (DRAM) access with silicon nanosheet transistors and metal capacitors. Such techniques are highly suitable for hierarchical design of n-number stacks. All gate metals can be shorted vertically with individual nanosheet transistors. All non-terminal capacitor metal plate (the terminal not connected to nanosheet transistor) can have common ground connection. Thinner nanosheet and wider capacitor design are for efficient DRAM. Source/drain connection can be staircase for n-stack design. Capacitor connections are shorted to each other and easy to hook up to ground. Gate terminals are sorted vertically and easy to connect.

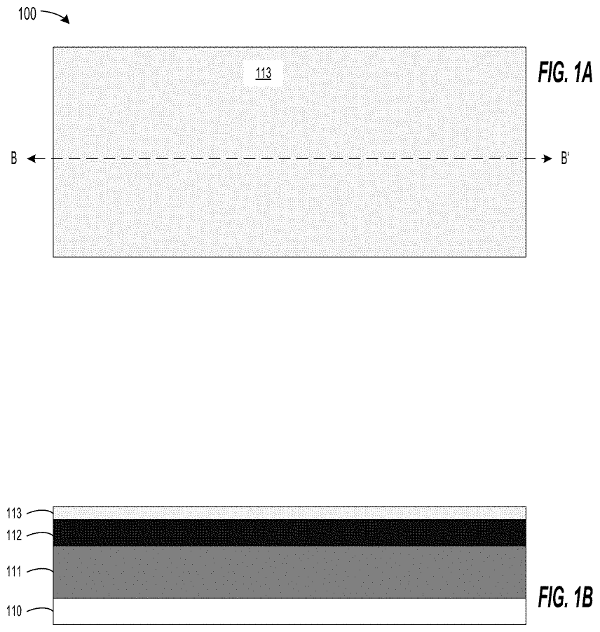

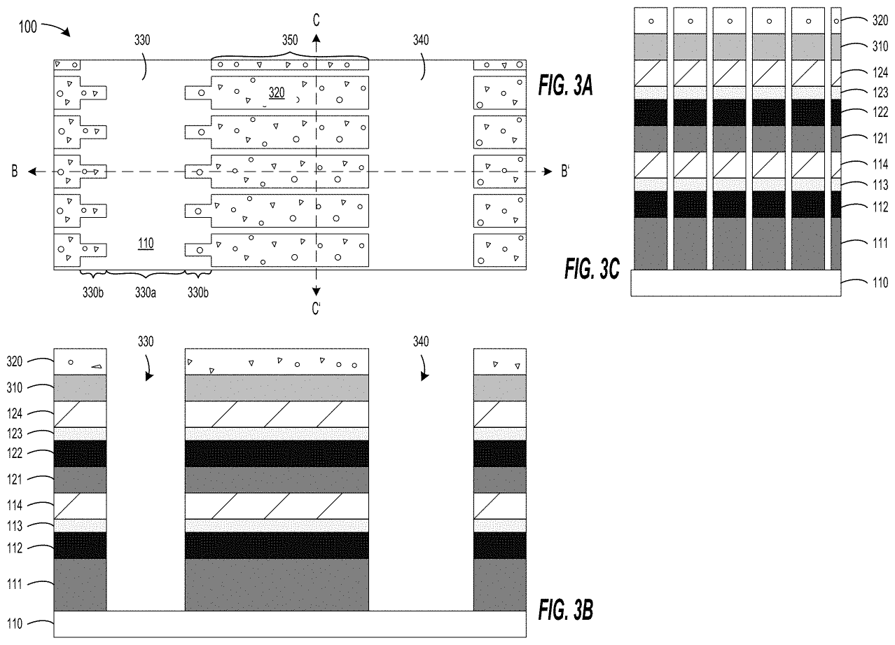

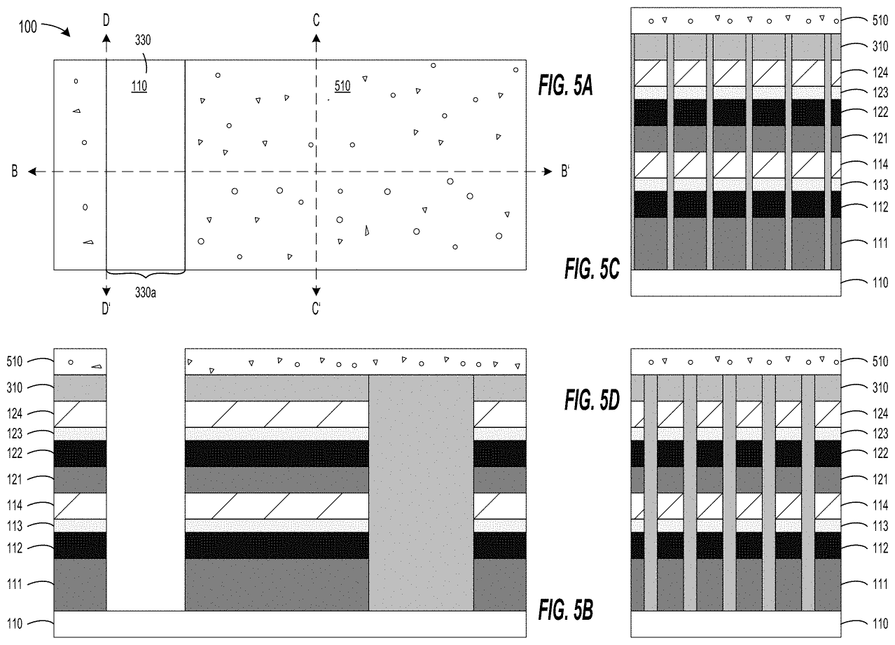

FIGS. 1A-23A show schematic views of various intermediary steps of a first exemplary method for fabricating a semiconductor structure 100 according to the some embodiments of the present disclosure. The semiconductor structure 100 can include 3D silicon nanosheet memories with metal capacitors. For example, the semiconductor structure 100 can include one or more vertically stacked horizontal dynamic random access memories (DRAMs) access with silicon nanosheet transistors and metal capacitors. In an embodiment, all gate metal are shorted vertically with individual nanosheet transistors, and all non-terminal capacitor metal plates, i.e., the terminals not connected to the nanosheet transistors, have common ground connection. In another embodiment, the metal capacitors may be wider than the nanosheet transistors for efficient DRAMs. FIGS. 1B-23B show cross-sectional views of the semiconductor structure 100 along cut lines BB′ shown in FIGS. 1A-23A, respectively, according to the some embodiments of the present disclosure. FIGS. 3C, 5C and 23C show cross-sectional views of the semiconductor structure 100 along cut lines CC′ shown in FIGS. 3A, 5A and 23A, respectively, according to the some embodiments of the present disclosure. FIGS. 5D, 9C-19C and 23D show cross-sectional views of the semiconductor structure 100 along cut lines DD′ shown in FIGS. 5A, 9A-19A and 23A, respectively, according to the some embodiments of the present disclosure. In the first method, nanosheets are sliced after epitaxial growth, and the isolation between the substrate and the nanosheets is done at a later stage.

As shown in FIGS. 1A and 1B, a substrate 110 is provided. The substrate 110 can include a Si or SiGe substrate. In an embodiment, the substrate 110 can be a lightly doped p-type silicon substrate. A lower dielectric layer 111 made of a first dielectric material can be deposited and formed on the substrate 110. In an embodiment, the lower dielectric layer 111 can be comparatively thick. A first lower metal layer 112, made of a first metal material, and a lower high-k dielectric (e.g., oxide) layer 113 can be deposited and formed on the lower dielectric layer 111 sequentially. For example, the lower high-k oxide layer 113 can include HfO₂ or ZrO₂, and can store electrical charges therein.

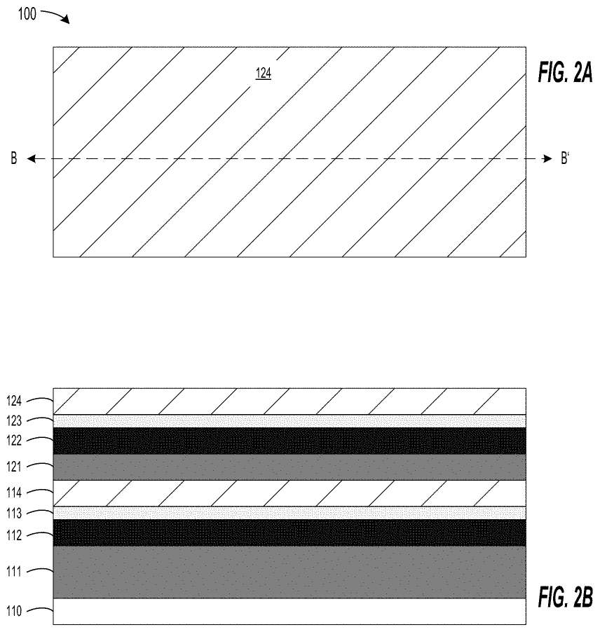

As shown in FIGS. 2A and 2B, a second lower metal layer 114 is deposited and formed on the lower high-k oxide layer 113. The second lower metal layer 114 can be made of a second metal material that is different from the first metal material. The lower dielectric layer 111, the first lower metal layer 112, the lower high-k oxide layer 113 and the second lower metal layer 114 can be collectively referred to as a lower stack of metal and dielectric (e.g., high-k oxide) layers and be used to fabricate a lower stack of 3D silicon nanosheet memories, e.g., nenosheet DRAMs, each with a nanosheet transistor and a metal capacitor connected to each other horizontally. An upper stack of metal and dielectric (e.g., high-k oxide) layers can then be deposited and formed on the lower stack. For example, the upper stack can include an upper dielectric layer 121, e.g., made of the first dielectric material, a first upper metal layer 122, e.g., made of the first metal material, an upper high-k dielectric (e.g., oxide) layer 123, e.g., made of HfO₂ or ZrO₂, and a second upper metal layer 124, e.g., made of the second metal material, which can be deposited and formed on the second lower metal layer 114 sequentially and be used to fabricate an upper stack of 3D silicon nanosheet memories, e.g., nanosheet DRAMs, each with a nanosheet transistor and a metal capacitor connected to each other horizontally. More stacks of metal and high-k oxide layers can be deposited and formed on the upper stack and be used to fabricate multiple vertical stacks of 3D silicon nanosheet memories each with a nanosheet memory and a metal capacitor connected to each other horizontally. In an embodiment, the comparatively thick lower dielectric layer 111 is thicker than the upper dielectric layer 121.

As shown in FIGS. 3A, 3B and 3C, a hard mask 310, e.g., a dielectric layer 310 made of a second dielectric material, is deposited and formed to cover the second upper metal layer 124 of the upper stack. In an embodiment, the second dielectric material is etched selectively with respect to the first dielectric material. An etch mask or photo resist layer 320, e.g., a DRAM slicing mask, is then formed on the dielectric layer 310, and the semiconductor structure 100 is directionally etched through the upper stack and the lower stack to uncover a top surface (e.g., a working surface) of the substrate 110, thus forming a plurality of semiconductor slices that are separated from one another, each of which has a nanosheet transistor opening area 330, a metal capacitor opening area 340, and a metal capacitor area 350 disposed between the nanosheet transistor opening area 330 and the metal capacitor opening area 340. In an embodiment, the nanosheet transistor opening area 330 is for nanosheet transistors to be formed therein, and includes a central portion 330a and an extended portion 330b. In another embodiment, the metal capacitor area 350 is for metal capacitors to be formed therein, which can be shorted to a common ground. In an embodiment, the metal capacitor area 350 is wider than the nanosheet transistor opening area 330 for the metal capacitors of the semiconductor structure 100 to have a higher capacitor value.

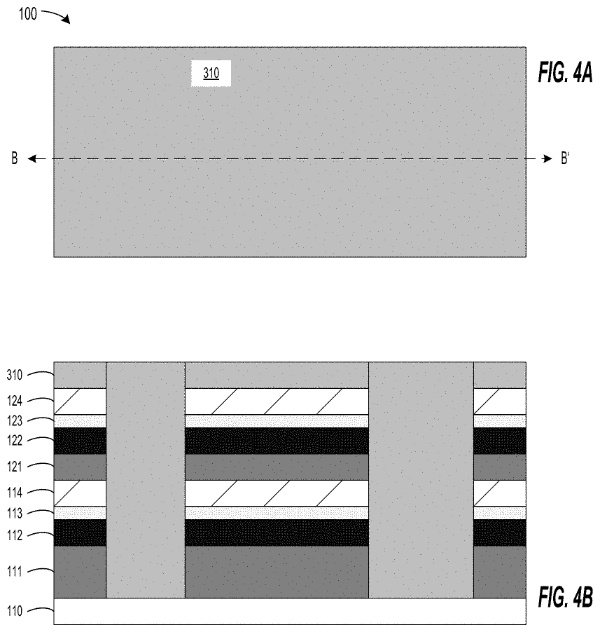

As shown in FIGS. 4A and 4B, the etch mask 320 is stripped off and removed, and the nanosheet transistor opening area 330 and the metal capacitor opening area 340 is filled with a dielectric material, e.g., the second dielectric material, of which the dielectric layer 310 is made.

As shown in FIGS. 5A-5D, an etch mask or photo resist layer 510 is deposited and formed on the dielectric layer 310, with a portion of the dielectric layer 310 that is filled in the central portion 330a of the nanosheet transistor opening area 330 uncovered, and then the semiconductor structure 100 is directionally etched through the upper stack and the lower stack within the central portion 330a of the nanosheet transistor opening area 330 to uncover the top surface of the substrate 110.

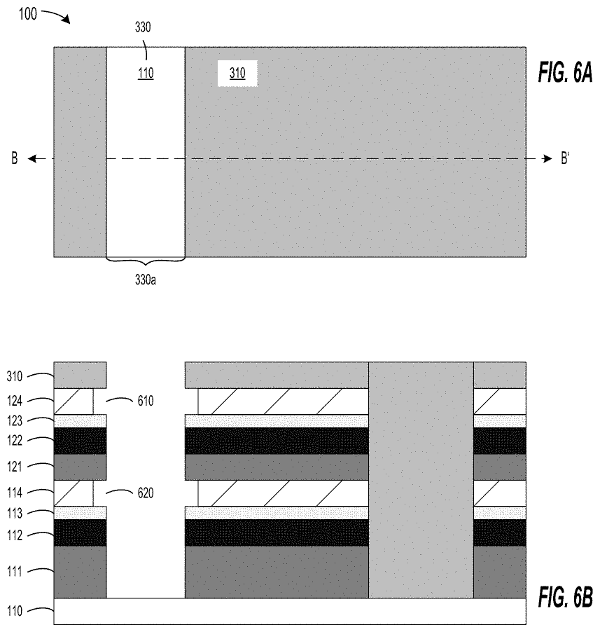

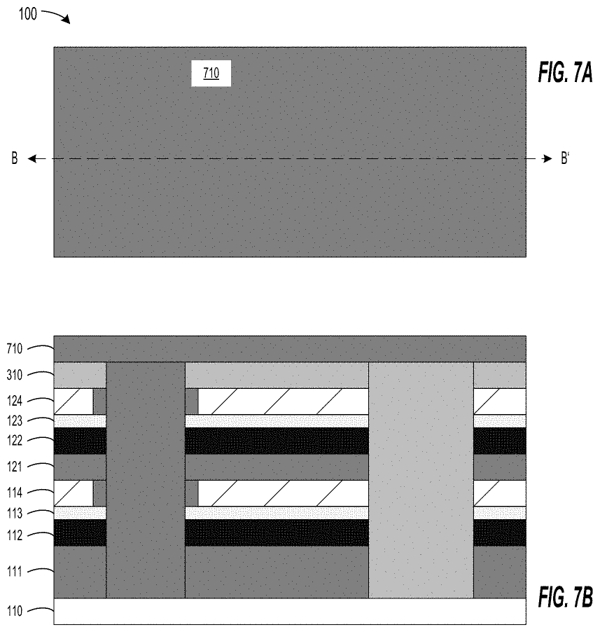

As shown in FIGS. 6A and 6B, the etch mask 510 is stripped off and removed, and then the second upper metal layer 124 and the second lower metal layer 114 are etched to form recesses 610 and 620, respectively, for a dielectric layer (shown in FIGS. 7A and 7B) to be filled therein. The recesses 610 and 620 (and the dielectric layer filled therein) can keep away the other capacitor metal terminals, e.g., made of the second upper metal layer 124 and the second lower metal layer 114, from the nanosheets transistors formed within the nanosheet transistor opening area 330.

As shown in FIGS. 7A and 7B, the recesses 610 and 620 (shown in FIG. 6B) and the central portion 330a of the nanosheet transistor opening area 330 are filled with a dielectric (i.e., insulating) layer 710, e.g., made of the first dielectric material. The dielectric layer 710 filled in the recesses 610 and 620 can make isolation between the second upper metal layer 124 and the second lower metal layer 114 and future nanosheet transistors formed within the nanosheet transistor opening area 330. The future nanosheet transistors will connect to the first upper metal layer 122 and the first lower metal layer 112.

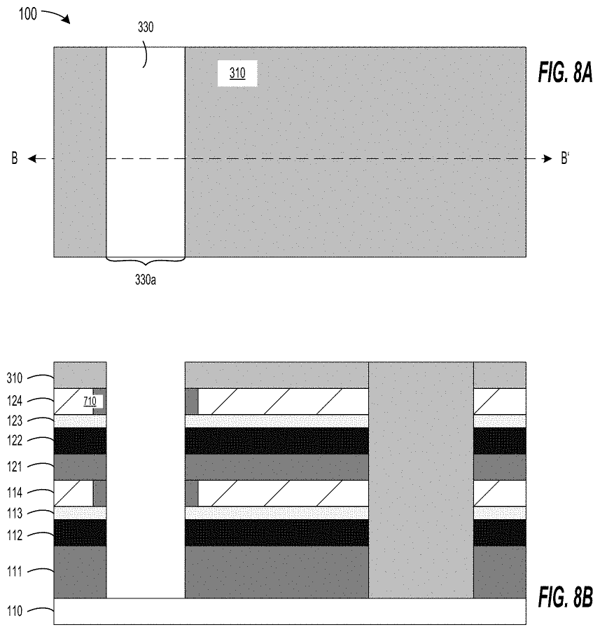

As shown in FIGS. 8A and 8B, the dielectric layer 710 formed on the dielectric layer 310 and filled within the central portion 330a of the nanosheet transistor opening area 330 is directionally etched to uncover the top surface of the lightly doped p-type silicon substrate 110.

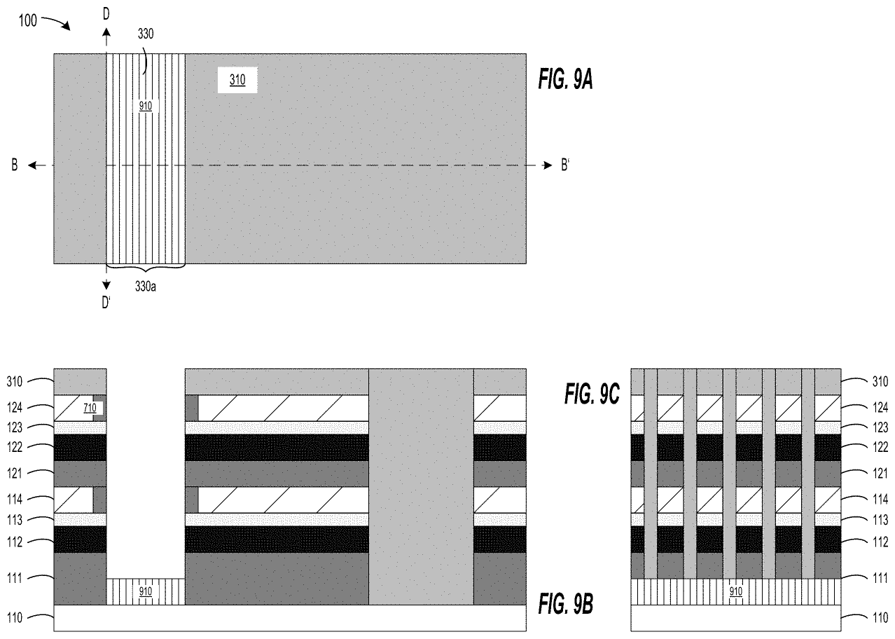

As shown in FIGS. 9A, 9B and 9C, a first (e.g., single crystal) SiGe layer 910, e.g., made of SiGe90, is epitaxially grown on the uncovered top surface of the lightly doped p-type silicon substrate 110. In an embodiment, the first SiGe layer 910 is thinner than the comparatively thick lower dielectric layer 111. The first SiGe layer 910 can be used to replace with an insulation layer in future process steps to keep the nanosheet transistors isolated from the substrate 110.

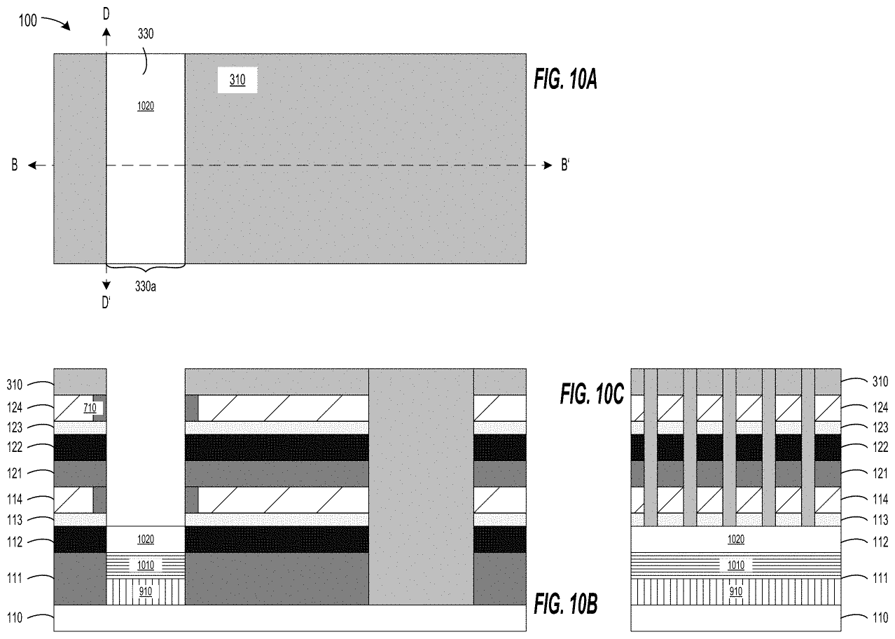

As shown in FIGS. 10A, 10B and 10C, a second (e.g., single crystal) SiGe layer 1010, e.g., made of SiGe30, that is different from the first SiGe layer 910, is epitaxially grown on the first SiGe layer 910 to maintain the single crystallinity. The second SiGe layer 1010 and the first SiGe layer 910 can be etched selectively with respect to each other. The second SiGe layer 1010 can be leveled with the comparatively thick lower dielectric layer 111, and, accordingly, a total thickness of the first SiGe layer 910 and the second SiGe layer 1010 can be equal to the thickness of the comparatively thick lower dielectric layer 111. A first lightly doped p-type silicon layer 1020 can be epitaxially grown on the second SiGe layer 1010. In an embodiment, the first lightly doped p-type silicon layer 1020 has a thickness such that the first lightly doped p-type silicon layer 1020 can cover and touch the first lower metal layer 112 entirely. In another embodiment, the first lightly doped p-type silicon layer 1020 can be thicker to further cover a portion of the lower high-k oxide layer 113 and/or a portion of the lower dielectric layer 111.

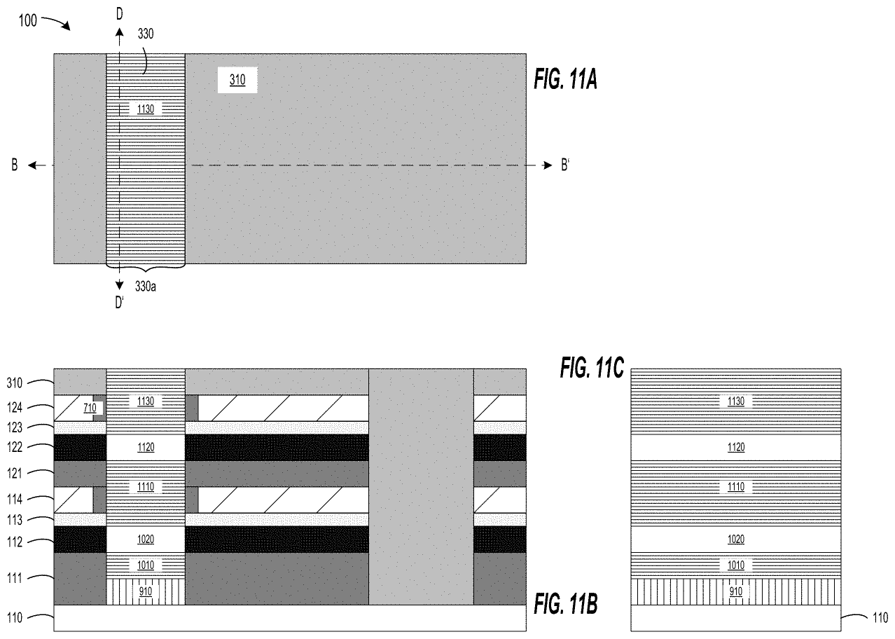

As shown in FIGS. 11A, 11B and 11C, the epitaxially-grown of SiGe30, lightly doped p-type silicon and SiGe30 layers of the semiconductor structure 100 can be finished by following the same strategy as illustrated in FIGS. 9A, 9B, 9C, 10A, 10B and 10C. For example, a third SiGe layer 1110, e.g., made of SiGe30, can be deposited and formed on the first lightly doped p-type silicon layer 1020, a second lightly doped p-type silicon layer 1120 can be deposited and formed on the third SiGe layer 1110, and a fourth SiGe layer 1130, e.g., made of SiGe30, can be deposited and formed on the second lightly doped p-type silicon layer 1120. In an embodiment, the third SiGe layer 1110, the second lightly doped p-type silicon layer 1120 and the fourth SiGe layer 1130 can be leveled with the upper dielectric layer 121, the first upper metal layer 122 and the dielectric layer 310, respectively. In an embodiment, the second lightly doped p-type silicon layer 1120 has a thickness such that the second lightly doped p-type silicon layer 1120 can cover and touch the first upper metal layer 122 entirely. In another embodiment, the second lightly doped p-type silicon layer 1120 can be thicker to further cover a portion of the upper high-k oxide layer 123 and/or a portion of the upper dielectric layer 121. For n stacks, the SiGe30 layer and the lightly doped p-type silicon layer can be repeated accordingly. In the example embodiment, the semiconductor structure 100 includes only one of the SiGe90, i.e., the first SiGe layer 910, which is formed at the bottom most within the nanosheet transistor opening area 330. In an embodiment, the semiconductor structure 100 can include more than one of the SiGe90 and one or more than one of the SiGe90 can be inserted in between the SiGe30 if any discontinuity is needed in the semiconductor structure 100.

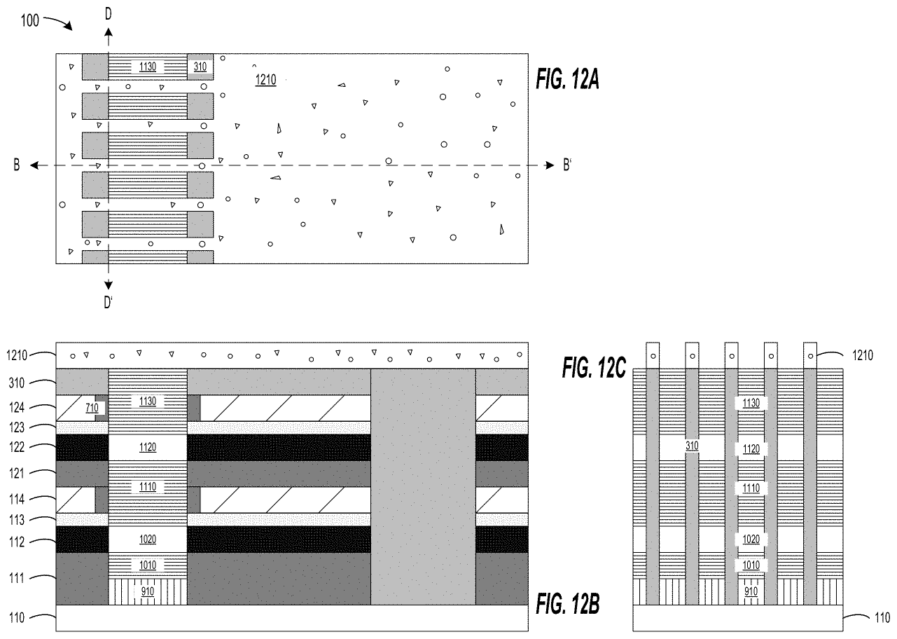

As shown in FIGS. 12A, 12B and 12C, an etch mask or photo resist layer 1210, e.g., a DRAM slicing mask, is formed on the dielectric layer 310, with the nanosheet transistor opening area 330, including the central portion 330a and the extended portion 330b, uncovered.

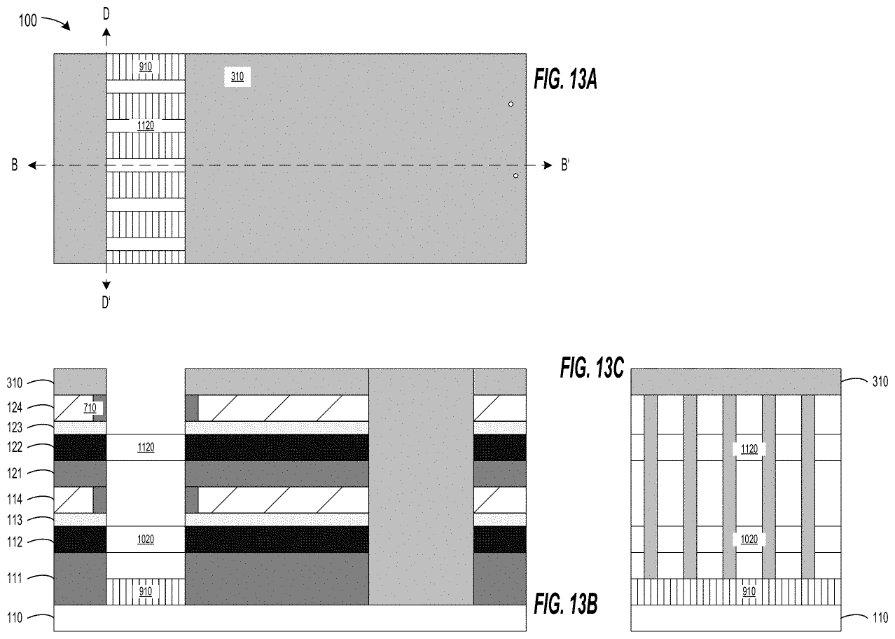

As shown in FIGS. 13A, 13B and 13C, the semiconductor structure 100 is directionally etched to remove the SiGe30, i.e., the second SiGe layer 1010, the third SiGe layer 1110 and the fourth SiGe layer 1130, with intact the first lightly doped p-type silicon layer 1020, the second lightly doped p-type silicon layer 1120 and the first SiGe layer 910, which is made of the SiGe90 and etched selectively with respect to the SiGe30. Then, the hard mask 1210 can be stripped off and removed. In an embodiment, for each suitability the final SiGe30 needs not be etched all the way. For example, partial etching is enough to access the SiGe30. In an embodiment, the SiGe30 can be removed by vapor-phase isotropic etching.

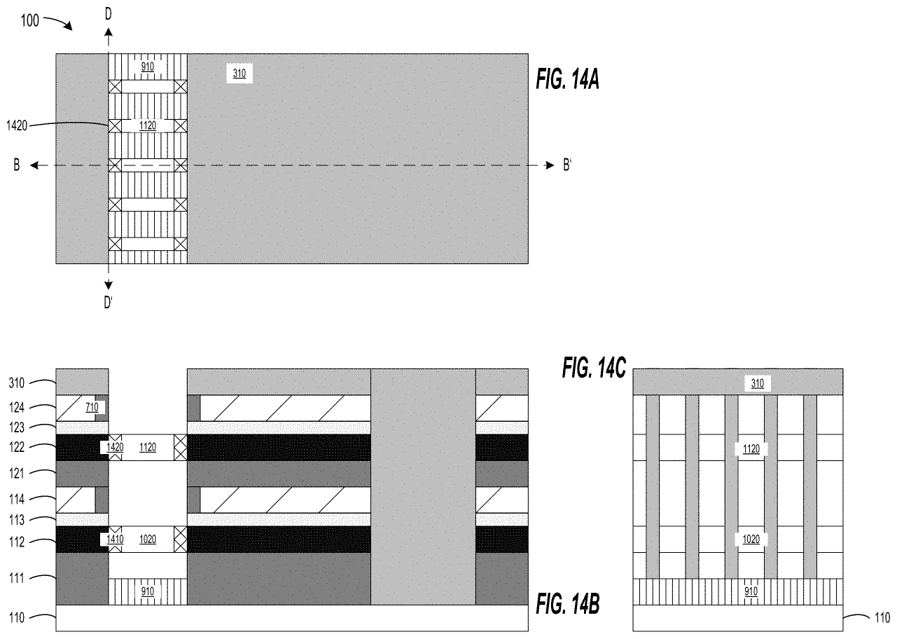

As shown in FIGS. 14A, 14B and 14C, the first lightly doped p-type silicon layer 1020 and the second lightly doped p-type silicon layer 1120 are annealed to develop a first silicide 1410 between the first lightly doped p-type silicon layer 1020 and the first lower metal layer 112 and a second silicide 1420 between the second lightly doped p-type silicon layer 1120 and the first upper metal layer 122, respectively.

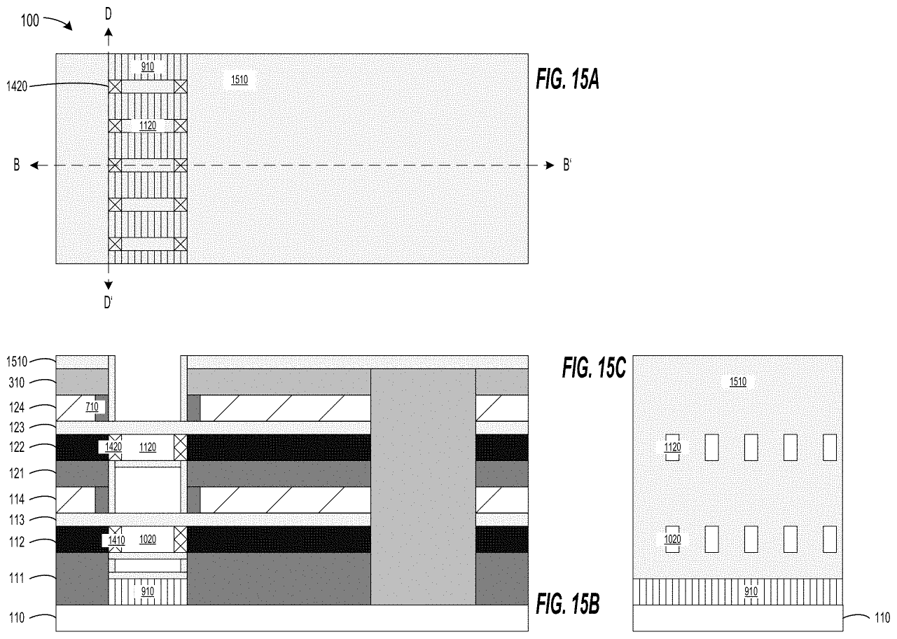

As shown in FIGS. 15A, 15B and 15C, a thin high-k dielectric layer 1510 is formed in a conformal deposition process, e.g., an atomic layer deposition (ALD) process, to surround the first lightly doped p-type silicon layer 1020 and the second lightly doped p-type silicon layer 1120, which are used as channels of the nanosheet transistors of the semiconductor structure 100. The ALD process is often performed at a low temperature, which makes less or even no damages on the components already fabricated, and can provide ultra-thin nano-layers in a precise manner on the first lightly doped p-type silicon layer 1020 and the second lightly doped p-type silicon layer 1120.

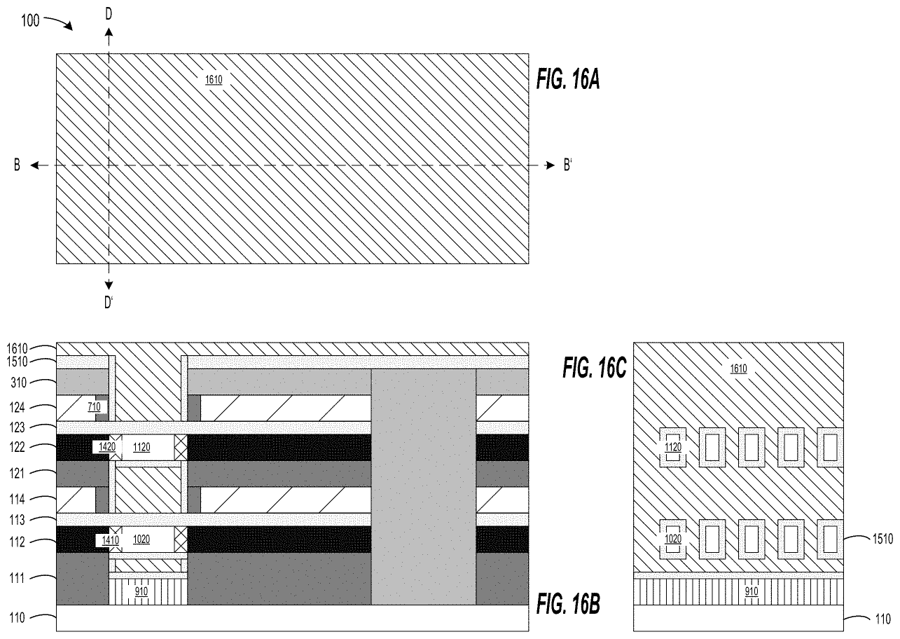

As shown in FIGS. 16A, 16B and 16C, a third metal layer 1610 is deposited and formed on the high-k dielectric layer 1510. In an embodiment, the third metal layer 1610 can be made of a third metal material that is different from the first and second metal materials.

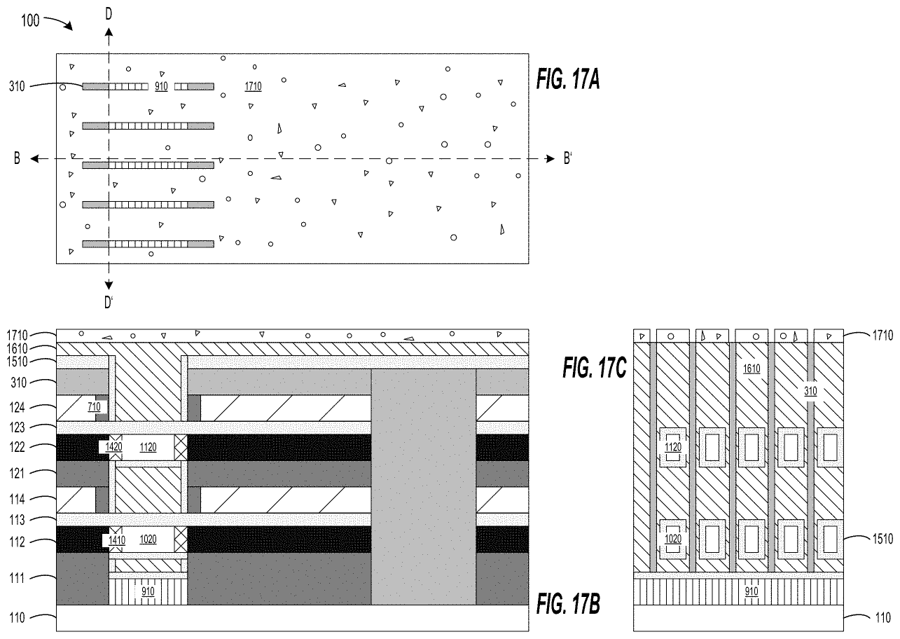

As shown in FIGS. 17A, 17B and 17C, an etch mask or photo resist layer 1710, e.g., a DRAM slicing mask, is formed on the third metal layer 1610, and the semiconductor structure 100 is directionally etched through the third metal layer 1610 and the high-k dielectric layer 1510 to uncover the SiGe90, i.e., the first SiGe layer 910. This etch opens access to the first SiGe layer 910.

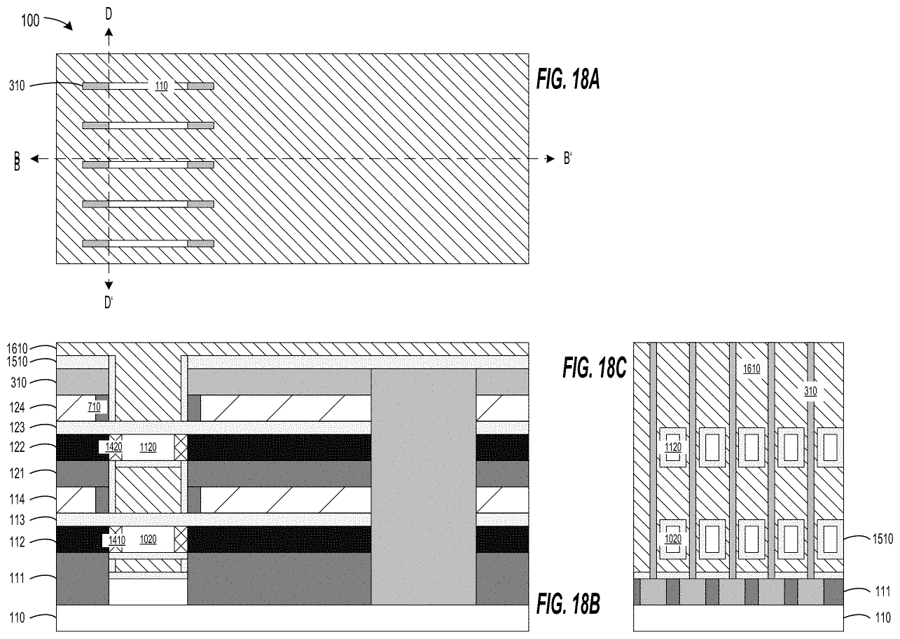

As shown in FIGS. 18A, 18B and 18C, the SiGe90, i.e., the first SiGe layer 910 (shown in FIGS. 17A, 17B and 17D), is etched and removed. Then, the hard mask 1710 (shown in FIGS. 17A, 17B and 17D) can be stripped off and removed.

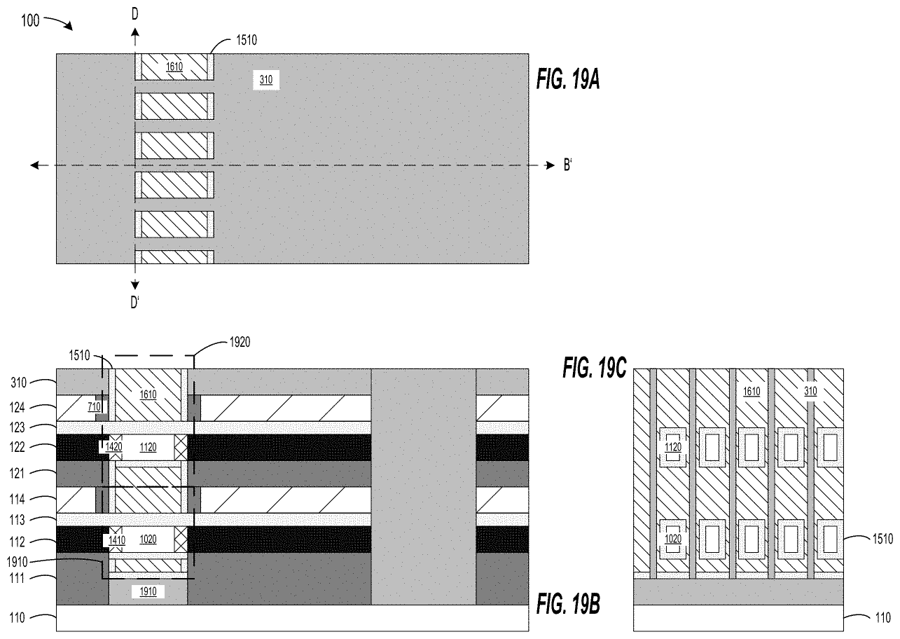

As shown in FIGS. 19A, 19B and 19C, a dielectric layer 1910, e.g., made of the second dielectric material, fills a space that is generated after the SiGe90, i.e., the first SiGe layer 910, is removed. A chemical-mechanical polishing (CMP) process can then be perform to planarize the dielectric layer 1910, the third metal layer 1610 and the high-k dielectric layer 1510.

The semiconductor structure 100 thus fabricated can include a (gate-all-around (GAA)) lower (or first) nanosheet transistor 1920 and an (GAA) upper (or second) nanosheet transistor 1930 that is stacked over the lower nanosheet transistor 1920. The lower nanosheet transistor 1920 includes a channel, i.e., the first lightly doped p-type silicon layer 1020, a gate region, i.e., the high-k dielectric layer 1510, that surrounds the channel and is surrounded by the third metal layer 1610, which can act as a gate electrode of the lower nanosheet transistor 1920, and source/drain (S/D) regions, i.e., the first silicide 1410, that are electrically connected to the first lower metal layer 112, which can act as S/D electrodes of the lower nanosheet transistor 1920. The dielectric layer 710 isolates the lower nanosheet transistor 1920 from the second lower metal layer 114, and the dielectric layer 1910 insulates the lower nanosheet transistor 1920 from the substrate 110. The upper nanosheet transistor 1930 includes a channel, i.e., the second lightly doped p-type silicon layer 1120, a gate region, i.e., the high-k dielectric layer 1510, that surrounds the channel and is surrounded by the third metal layer 1610, which can act as a gate electrode of the upper nanosheet transistor 1520, and source/drain regions, i.e., the second silicide 1420, that are electrically connected to the first upper metal layer 122, which can act as S/D electrodes of the upper nanosheet transistor 1930. The dielectric layer 710 isolates the upper nanosheet transistor 1930 from the second upper metal layer 124. The gate regions of the lower nanosheet transistor 1920 and the upper nanosheet transistor 1930 are shorted by the third metal layer 1610.

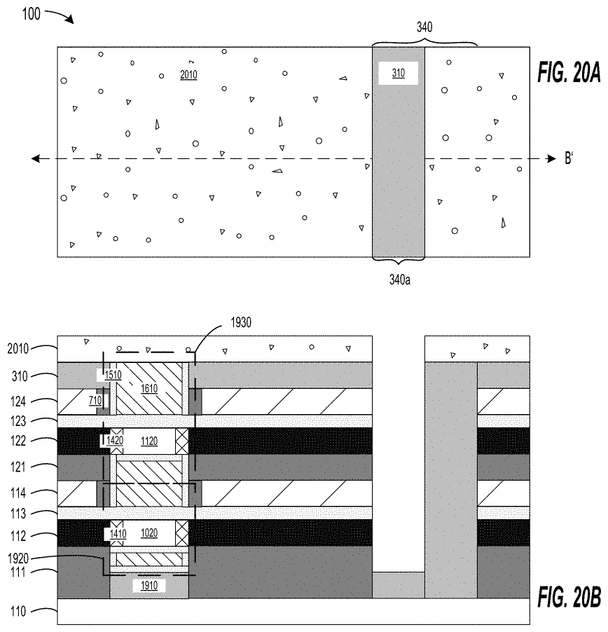

As shown in FIGS. 20A and 20B, a hard mask or photo resist layer 2010 is deposited and formed to cover the top surface of the semiconductor structure 100, with a portion 340a of the metal capacitor opening area 340 uncovered, and the semiconductor structure 100 is directional etched until uncovering a portion of the first lower metal layer 112. In an embodiment, the semiconductor structure 100 can be directionally etched until uncovering the top surface of the substrate 110.

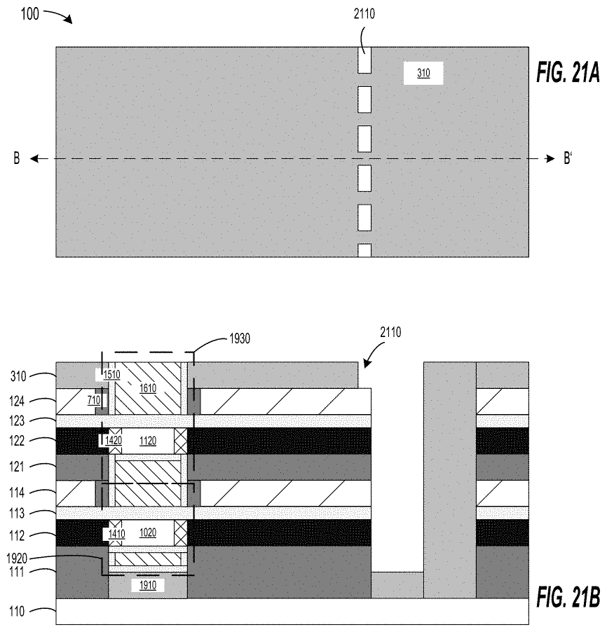

As shown in FIGS. 21A and 21B, the hard mask 2010 (shown in FIGS. 20A and 20B) is stripped off and removed, and a portion of the dielectric layer 310 formed on the second upper metal layer 124, adjacent to a trench that is formed after the semiconductor structure 100 is directionally etched, is etched to broaden the access for metal layers, e.g., the first lower metal layer 112 and the first upper metal layer 122, inside the trench so as to form spaces 2110. For example, an ellipsoidal etching process can be performed to etch lateral and vertical sides of the dielectric layer 310.

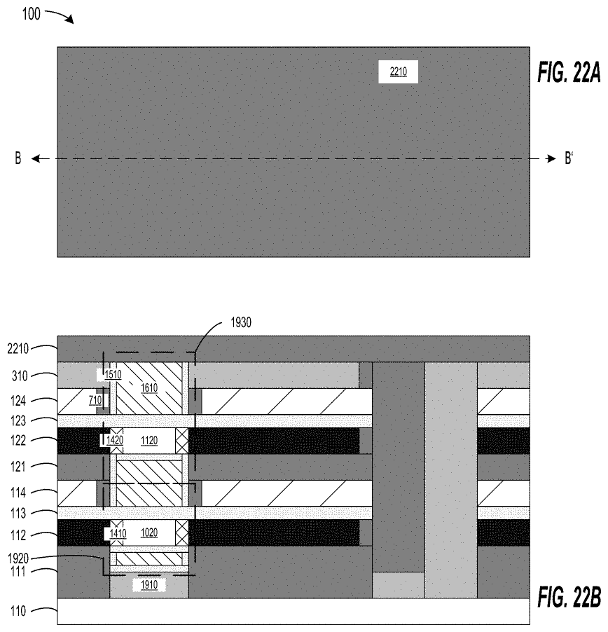

As shown in FIGS. 22A and 22B, a portion of the first lower metal layer 112 and the first upper metal layer 122 are etched and recessed, and a dielectric layer 2210, e.g., made of the first dielectric material (an insulating material), fills the trench, the spaces 2110, and spaces that are generated after the portion of the first lower metal layer 112 and the first upper metal layer 122 is etched and recessed. The dielectric layer 2210 can isolate the first lower metal layer 112 and the first upper metal layer 122 from common ground connection that will short the second lower metal layer 114 and the second upper metal layer 124 of different hierarchies.

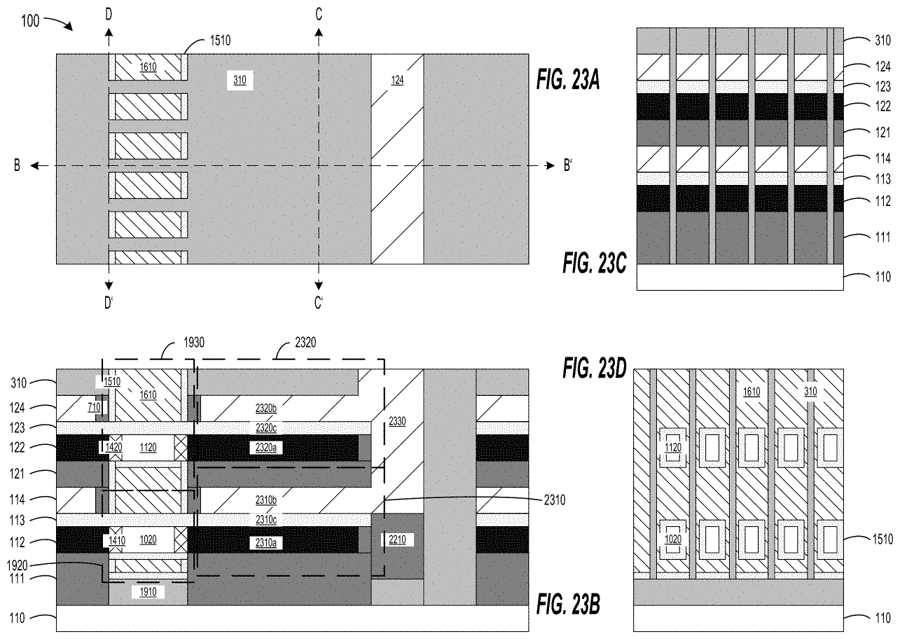

As shown in FIGS. 23A-23D, the dielectric layer 2210 is directionally etched until reaching a portion of the second lower metal layer 114, with the dielectric layer 2210 that fills the spaces 2110 also removed. In an embodiment, the dielectric layer 2210 can be directionally etched until reaching the entire second lower metal layer 114 within the trench. Then, a metal material 2330, e.g., the second metal material, can fill spaces that are generated after the dielectric layer 2210 is directionally etched, and the CMP process can be performed to planarize the metal material 2330.

The semiconductor structure 100 thus further fabricated can further include a lower metal capacitor 2310 and an upper metal capacitor 2320 that is stacked over the lower metal capacitor 2310. The lower metal capacitor 2310 is electrically connected to the lower nanosheet transistor 1920 horizontally, and includes a first lower metal plate 2310a, i.e., the first lower metal layer 112, that is electrically connected to the S/D electrodes of the lower nanosheet transistor 1920, a second lower metal plate (or non-terminal metal plate) 2310b, i.e., the second lower metal layer 114, that is isolated by the dielectric layer 710 from the lower nanosheet transistor 1920 and is not electrically connected to the lower nanosheet transistor 1920, and a lower dielectric layer 2310c, i.e., the lower high-k oxide layer 113, that is sandwiched between the first lower metal plate 2310a and the second lower metal plate 2310b for storing electrical charges flowing from the lower nanosheet transistor 1920. The upper metal capacitor 2320 is electrically connected to the upper nanosheet transistor 1930 horizontally, and includes a first upper metal plate 2320a, i.e., the first upper metal layer 122, that is electrically connected to the S/D electrodes of the upper nanosheet transistor 1930, a second upper metal plate (or non-terminal metal plate) 2320b, i.e., the second upper metal layer 124, that is isolated by the dielectric layer 710 from the upper nanosheet transistor 1930 and is not electrically connected to the upper nanosheet transistor 1930, and an upper dielectric layer 2320c, i.e., the upper high-k oxide layer 123, that is sandwiched between the first upper metal plate 2320a and the second upper metal plate 2320b for storing electrical charges flowing from the upper nanosheet transistor 1930. The non-terminal metal plates of the lower metal capacitor 2310 and the upper metal capacitor 2320, i.e., the second lower metal plate 2310b and the second upper metal plate 2320b, can be electrically connected, e.g., by the metal material 2330, and have common ground connection and be shorted to a common ground.

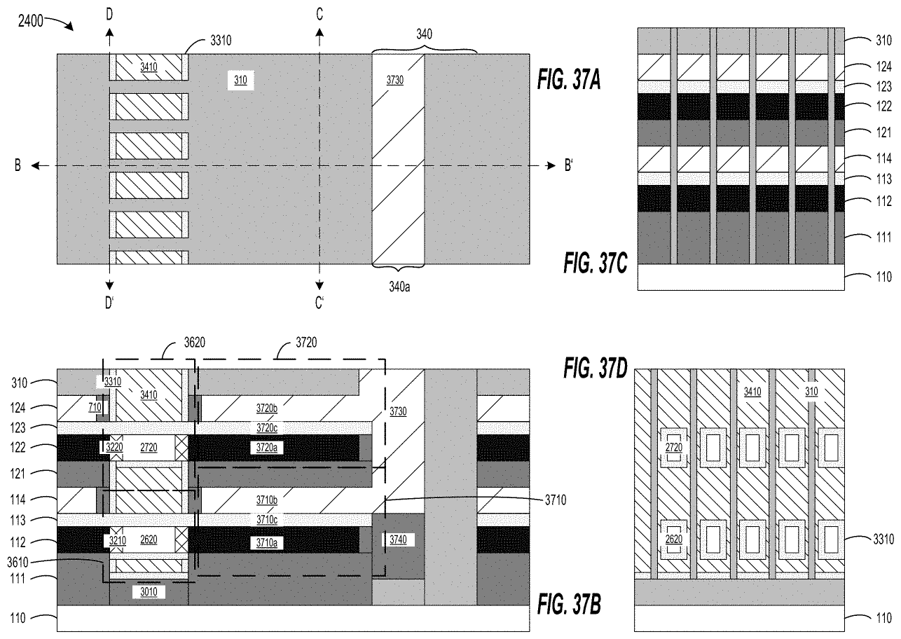

FIGS. 24A-37A show schematic views of various intermediary steps of a second exemplary method for fabricating a semiconductor structure 2400 according to the some embodiments of the present disclosure. The semiconductor structure 2400 can include 3D silicon nanosheet memories with metal capacitors. For example, the semiconductor structure 2400 can include one or more vertically stacked horizontal DRAMs access with silicon nanosheet transistors and metal capacitors. In an embodiment, all gate metal are shorted vertically with individual nanosheet transistors, and all non-terminal capacitor metal plates, i.e., the terminals not connected to the nanosheet transistors, have common ground connection. In another embodiment, the nanosheet transistors may be narrower than the metal capacitors for efficient DRAMs. FIGS. 24B-37B show cross-sectional views of the semiconductor structure 2400 along cut lines BB′ shown in FIGS. 24A-37A, respectively, according to the some embodiments of the present disclosure. FIG. 37C shows a cross-sectional view of the semiconductor structure 2400 along a cut line CC′ shown in FIG. 37A according to the some embodiments of the present disclosure. FIGS. 24C-36C and 37D show cross-sectional views of the semiconductor structure 2400 along cut lines DD′ shown in FIGS. 24A-37A, respectively, according to the some embodiments of the present disclosure. In the second method, nanosheets are sliced before epitaxial growth, which makes a self-aligned confined space for the epitaxial growth, and the isolation between the substrate and the nanosheets is done at a later stage.

As shown in FIGS. 24A, 24B and 24C, which follow FIGS. 7A and 7B, an etch mask 2410, e.g., a DRAM nanosheet mask, is formed on the dielectric layer 710, and the semiconductor structure 2400 is directionally etched through a portion of the dielectric layer 710 that is not covered by the etch mask 2410 to uncover the top surface of the substrate 110. Advantages of this step from the first method include (i) etching only one material, i.e., the dielectric layer 710; (ii) defining spaces for nanosheet transistors; and (iii) no need to etch the substrate 110 further.

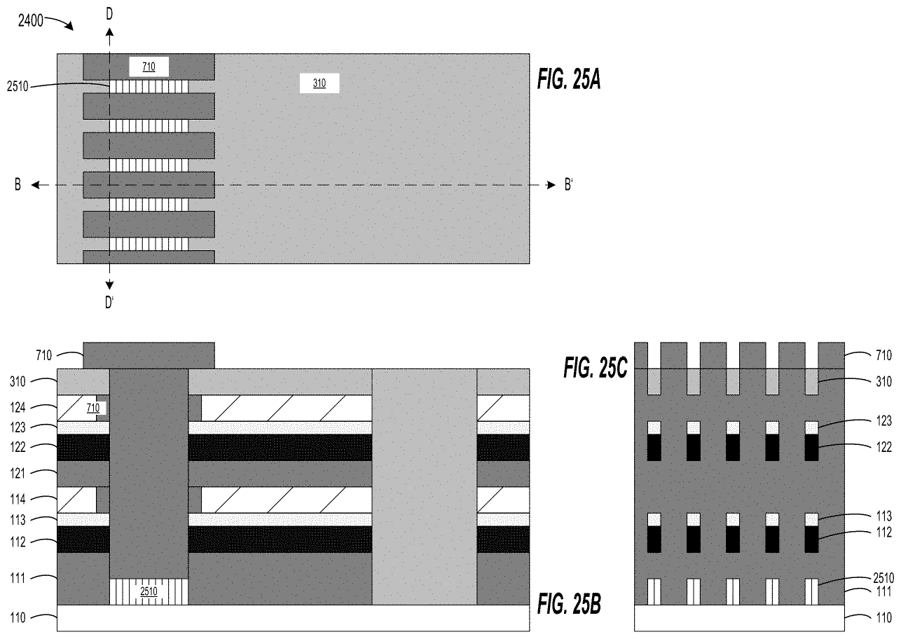

As shown in FIGS. 25A, 25B and 25C, the etch mask 2410 is stripped off and removed, and a first SiGe layer 2510, e.g., made of SiGe90, is epitaxially grown on the uncovered top surface of the lightly doped p-type silicon substrate 110. In an embodiment, the first SiGe layer 2510 is thinner than the comparatively thick lower dielectric layer 111. The first SiGe layer 2510 is used to replace with an insulation layer in future process steps to keep the nanosheet transistors isolated from the substrate 110.

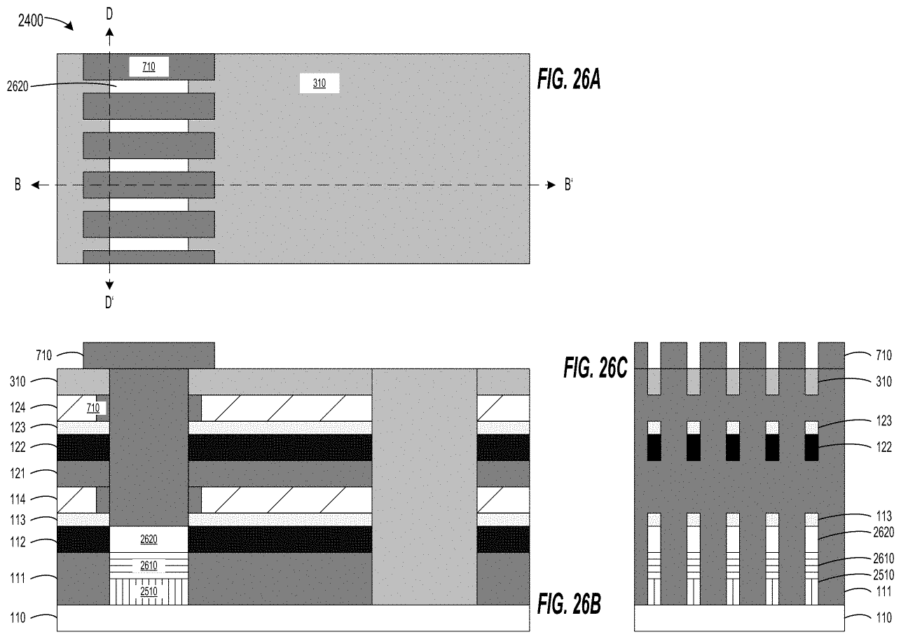

As shown in FIGS. 26A, 26B and 26C, a second SiGe layer 2610, e.g., made of SiGe30, that is different from the first SiGe layer 2510, is epitaxially grown on the first SiGe layer 2510 to maintain the single crystallinity. The second SiGe layer 2610 can be leveled with the lower dielectric layer 111, and, accordingly, a total thickness of the first SiGe layer 2510 and the second SiGe layer 2610 can be equal to the thickness of the lower dielectric layer 111. A first lightly doped p-type silicon layer 2620 can be epitaxially grown on the second SiGe layer 2610. In an embodiment, the first lightly doped p-type silicon layer 2620 has a thickness such that the first lightly doped p-type silicon layer 2620 can touch the first lower metal layer 112 entirely. In another embodiment, the first lightly doped p-type silicon layer 2620 can be thicker to further cover a portion of the lower high-k oxide layer 113 and/or a portion of the lower dielectric layer 111.

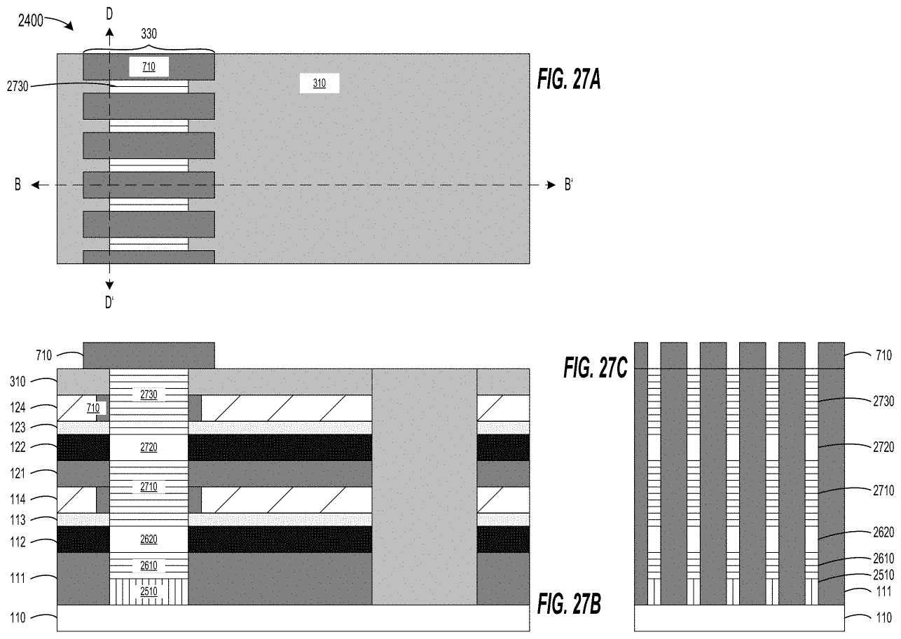

As shown in FIGS. 27A, 27B and 27C, the epitaxially-grown of SiGe30, lightly doped p-type silicon and SiGe30 layers of the semiconductor structure 2400 can be finished by following the same strategy as illustrated in FIGS. 25A, 25B, 25C, 26A, 26B and 26C. For example, a third SiGe layer 2710, e.g., made of SiGe30, can be deposited and formed on the first lightly doped p-type silicon layer 2620, a second lightly doped p-type silicon layer 2720 is deposited and formed on the third SiGe layer 2710, and a fourth SiGe layer 2730, e.g., made of SiGe30, can be deposited and formed on the second lightly doped p-type silicon layer 2720. In an embodiment, the third SiGe layer 2710, the second lightly doped p-type silicon layer 2720 and the fourth SiGe layer 2730 can be leveled with the upper dielectric layer 121, the first upper metal layer 122 and the dielectric layer 310, respectively. In an embodiment, the second lightly doped p-type silicon layer 2720 has a thickness such that the second lightly doped p-type silicon layer 2720 can touch the first upper metal layer 122 entirely. In another embodiment, the second lightly doped p-type silicon layer 2720 can be thicker to further cover a portion of the upper high-k oxide layer 123 and/or a portion of the upper dielectric layer 121. For n stacks, the SiGe30 layer and the lightly doped p-type silicon layer can be repeated accordingly. In the example embodiment, the semiconductor structure 2400 includes only one of the SiGe90, i.e., the first SiGe layer 2510, which is formed at the bottom most within the nanosheet transistor opening area 330. In an embodiment, the semiconductor structure 2400 can include more than two of the SiGe90 and one or more than one of the SiGe90 can be inserted in between the SiGe30 if any discontinuity is needed in the semiconductor structure 2400.

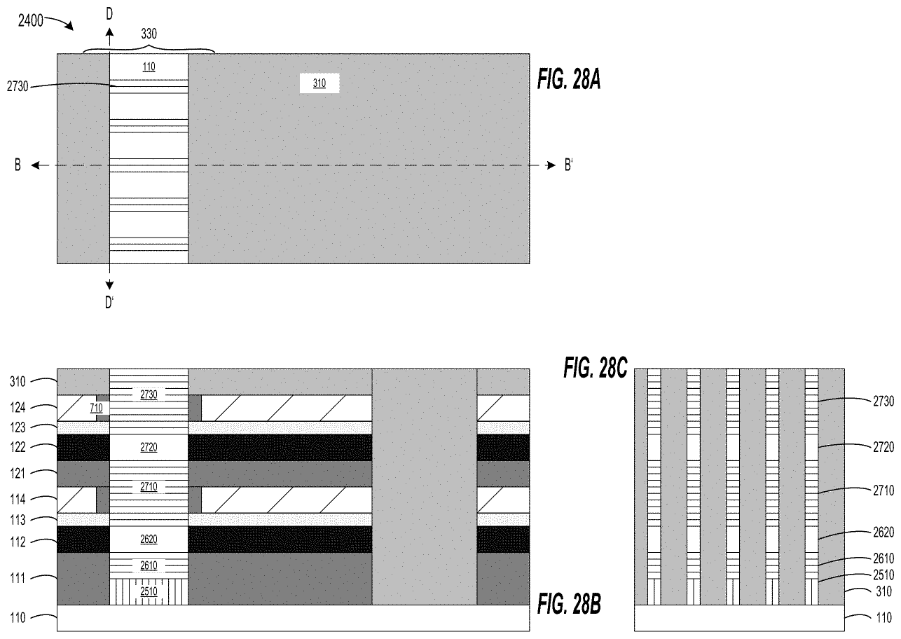

As shown in FIGS. 28A, 28B and 28C, the semiconductor structure 2400 within the central portion 330a of the nanosheet transistor opening area 330 is directionally etched to remove the dielectric layer 710 until uncovering the top surface of the substrate 110.

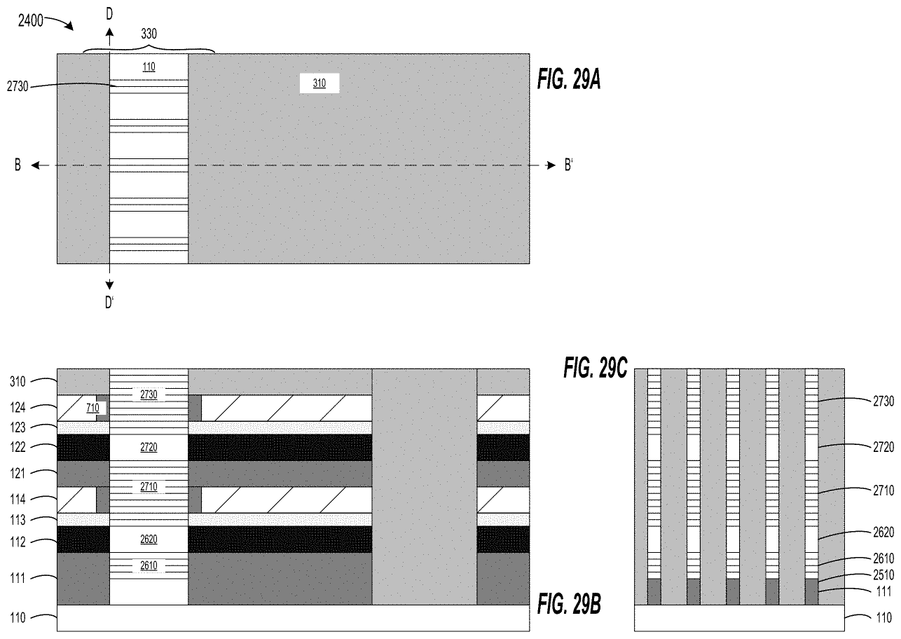

As shown in FIGS. 29A, 29B and 29C, the SiGe90, i.e., the first SiGe layer 2510, is etched and removed.

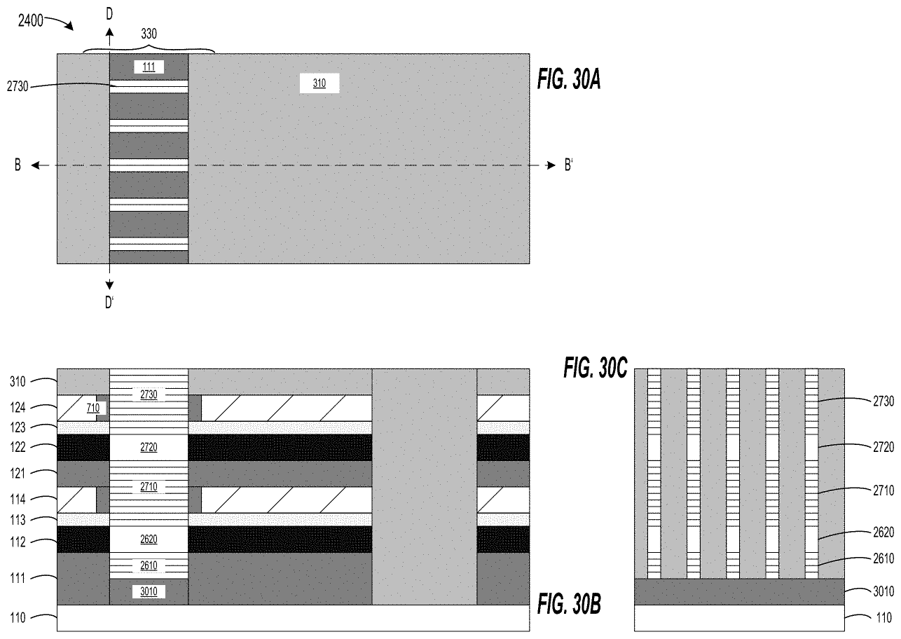

As shown in FIGS. 30A, 30B and 30C, a dielectric layer 3010, e.g., made of the first dielectric layer material, fills spaces that are generated after the first SiGe layer 2510 is removed. The dielectric layer 3010 will create an isolation layer between the substrate 110 and the nanosheet transistors. The SiGe30, i.e., the second SiGe layer 2610, the third SiGe layer 2710 and the fourth SiGe layer 2730, can be partially covered by the dielectric layer 3010 without any problem in the process flow.

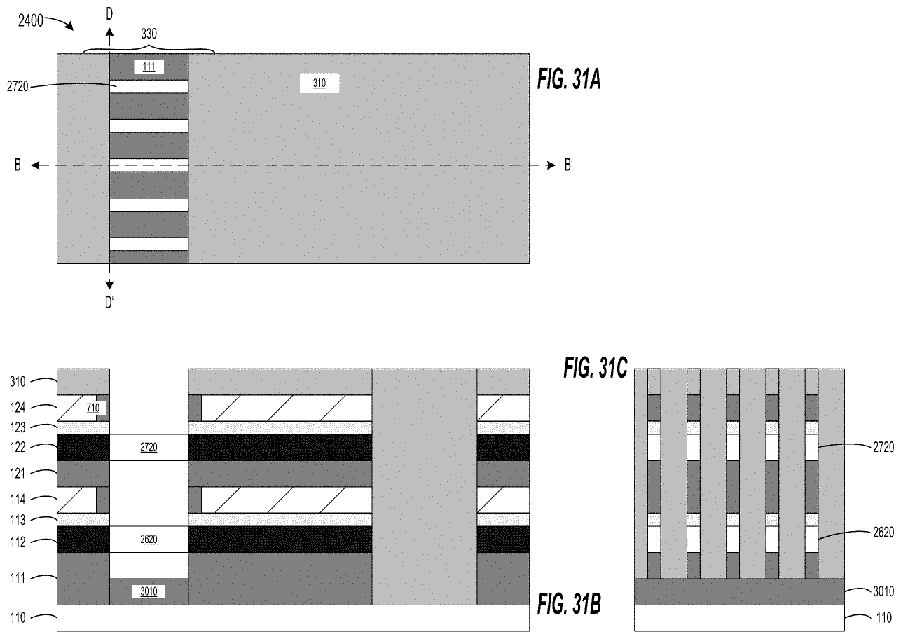

As shown in FIGS. 31A, 31B and 31C, the SiGe30, i.e., the second SiGe layer 2610, the third SiGe layer 2710 and the fourth SiGe layer 2730, is etched and removed.

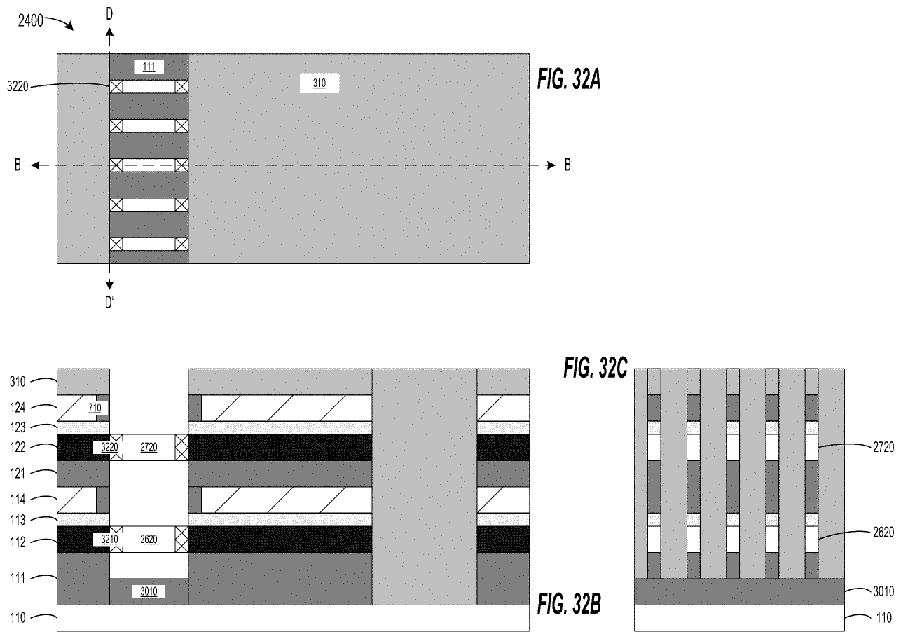

As shown in FIGS. 32A, 32B and 32C, the first lightly doped p-type silicon layer 2620 and the second lightly doped p-type silicon layer 2720 are annealed to develop a first silicide 3210 between the first lightly doped p-type silicon layer 2620 and the first lower metal layer 112 and a second silicide 3220 between the second lightly doped p-type silicon layer 2720 and the first upper metal layer 122, respectively.

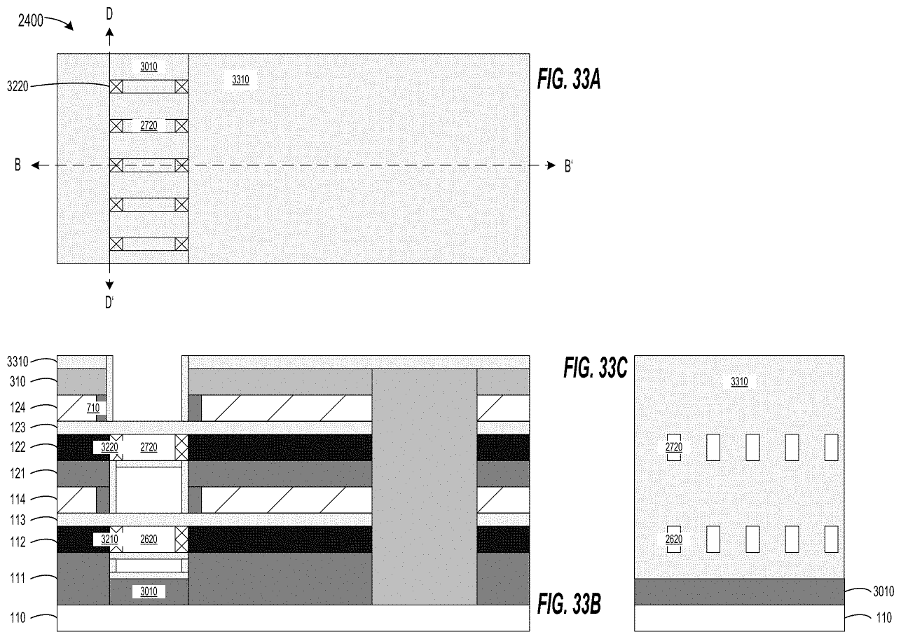

As shown in FIGS. 33A, 33B and 33C, a thin high-k dielectric layer 3310 is formed in a conformal deposition process to surround the first lightly doped p-type silicon layer 2620 and the second lightly doped p-type silicon layer 2720, which are used as channels of the nanosheet transistors of the semiconductor structure 2400. The ALD process can provide ultra-thin nano-layers in a precise manner on the first lightly doped p-type silicon layer 2620 and the second lightly doped p-type silicon layer 2720.

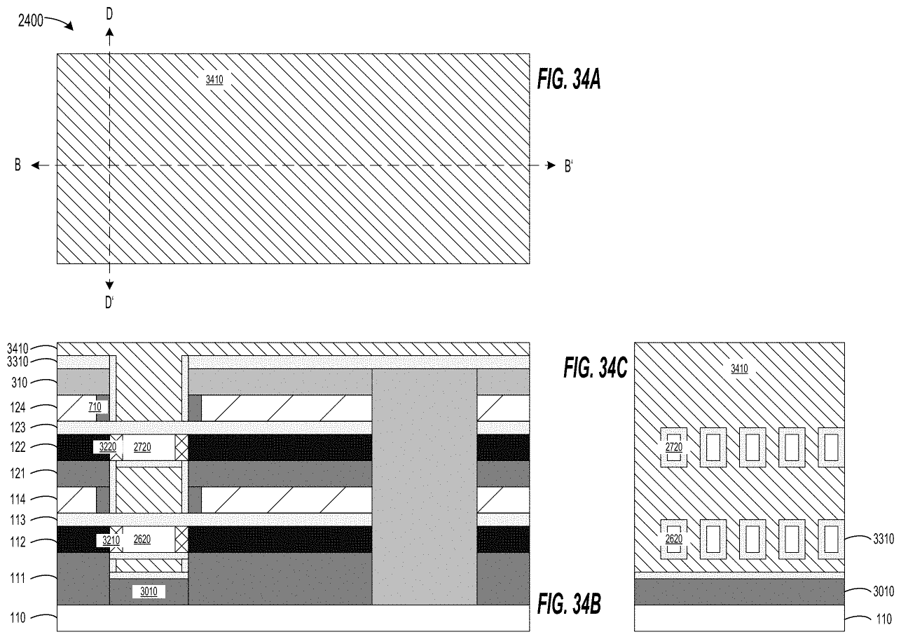

As shown in FIGS. 34A, 34B and 34C, a third metal layer 3410 is deposited and formed on the high-k dielectric layer 3310.

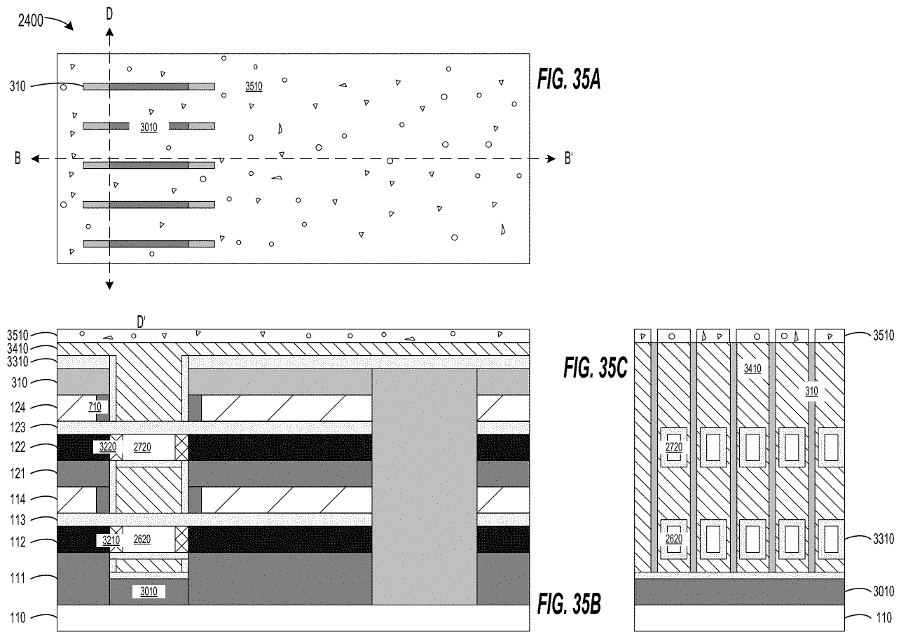

As shown in FIGS. 35A, 35B and 35C, an etch mask or photo resist layer 3510, e.g., a DRAM slicing mask, is formed on the third metal layer 3410, and the semiconductor structure 2400 is directionally etched through the third metal layer 3410 and the high-k dielectric layer 3310.

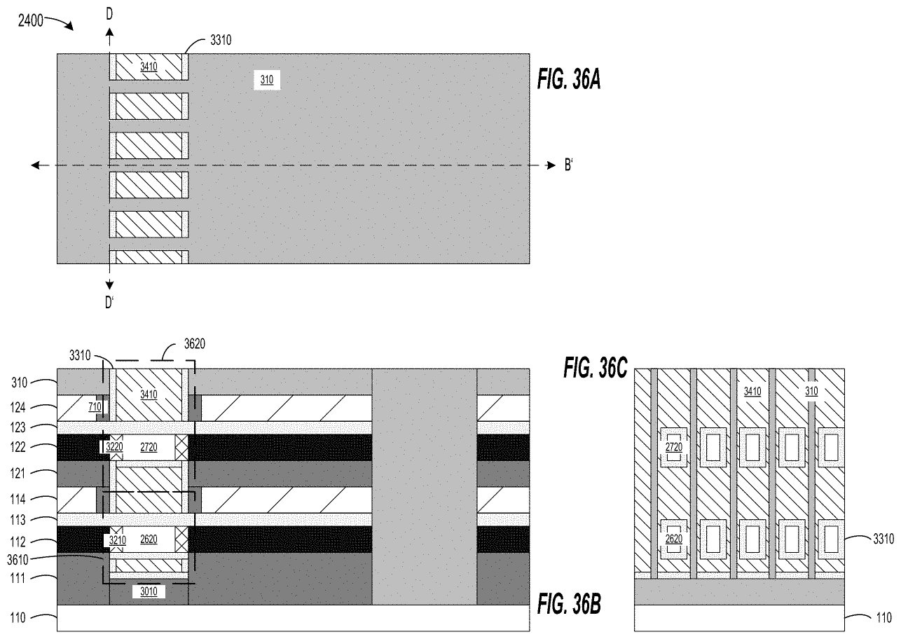

As shown in FIGS. 36A, 36B and 36C, the etch mask 3510 is stripped off and removed, and the CMP process can then be perform to planarize the dielectric layer 310, the third metal layer 3410 and the high-k dielectric layer 3310.

The semiconductor structure 2400 thus fabricated can include a (GAA) lower (or first) nanosheet transistor 3610 and an (GAA) upper (or second) nanosheet transistor 3620 that is stacked over the lower nanosheet transistor 3610. The lower nanosheet transistor 3610 includes a channel, i.e., the first lightly doped p-type silicon layer 2620, a gate region, i.e., the high-k dielectric layer 3310, that surrounds the channel and is surrounded by the third metal layer 3410, which can act as a gate electrode of the lower nanosheet transistor 3610, and source/drain (S/D) regions, i.e., the first silicide 3210, that are electrically connected to the first lower metal layer 112, which can act as S/D electrodes of the lower nanosheet transistor 3610. The dielectric layer 710 isolates the lower nanosheet transistor 3610 from the second lower metal layer 114, and the dielectric layer 3010 insulates the lower nanosheet transistor 3610 from the substrate 110. The upper nanosheet transistor 3620 includes a channel, i.e., the second lightly doped p-type silicon layer 2720, a gate region, i.e., the high-k dielectric layer 3310, that surrounds the channel and is surrounded by the third metal layer 3410, which can act as a gate electrode of the upper nanosheet transistor 3620, and source/drain regions, i.e., the second silicide 3220, that are electrically connected to the first upper metal layer 122, which can act as S/D electrodes of the upper nanosheet transistor 3620. The dielectric layer 710 isolates the upper nanosheet transistor 3620 from the second upper metal layer 124. The gate regions of the lower nanosheet transistor 3610 and the upper nanosheet transistor 3620 are shorted by the third metal layer 3410.

As shown in FIGS. 37A, 37B, 37C and 37D, which follow FIGS. 20A, 20B, 21A, 21B, 22A and 22B, a dielectric layer 3740, e.g., made of the first dielectric material, can fill a trench that is formed after the semiconductor structure 2400 within a portion 340a of the metal capacitor opening area 340 is etched, until the dielectric layer 3740 covers the lower high-k oxide layer 113, with the second lower metal layer 114 and the second upper metal layer 124 stilled uncovered. Then, a metal material 3730, e.g., the second metal material, can fill the remaining trench, and the CMP process can be performed to planarize the metal material 3730.

The semiconductor structure 2400 thus further fabricated can further include a lower metal capacitor 3710 and an upper metal capacitor 3720 that is stacked over the lower metal capacitor 3710. The lower metal capacitor 3710 is electrically connected to the lower nanosheet transistor 3610 horizontally, and includes a first lower metal plate 3710a, i.e., the first lower metal layer 112, that is electrically connected to the S/D electrodes of the lower nanosheet transistor 3610, a second lower metal plate (or non-terminal metal plate) 3710b, i.e., the second lower metal layer 114, that is isolated by the dielectric layer 710 from the lower nanosheet transistor 3610 and is not electrically connected to the lower nanosheet transistor 3610, and a lower dielectric layer 3710c, i.e., the lower high-k oxide layer 113, that is sandwiched between the first lower metal plate 3710a and the second lower metal plate 3710b for storing electrical charges flowing from the lower nanosheet transistor 3610. The upper metal capacitor 3720 is electrically connected to the upper nanosheet transistor 3620 horizontally, and includes a first upper metal plate 3720a, i.e., the first upper metal layer 122, that is electrically connected to the S/D electrodes of the upper nanosheet transistor 3620, a second upper metal plate (or non-terminal metal plate) 3720b, i.e., the second upper metal layer 124, that is isolated by the dielectric layer 710 from the upper nanosheet transistor 3620 and is not electrically connected to the upper nanosheet transistor 3620, and an upper dielectric layer 3720c, i.e., the upper high-k oxide layer 123, that is sandwiched between the first upper metal plate 3720a and the second upper metal plate 3720b for storing electrical charges flowing from the upper nanosheet transistor 3620. The non-terminal metal plates of the lower metal capacitor 3710 and the upper metal capacitor 3720, i.e., the second lower metal plate 3710b and the second upper metal plate 3720b, can be electrically connected, e.g., by the metal material 3730, and have common ground connection and be shorted to a common ground.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the present disclosure are not intended to be limiting. Rather, any limitations to embodiments of the present disclosure are presented in the following claims.

What is claimed is:

1. A method for fabricating a semiconductor structure, comprising:
forming over a substrate a lower stack of alternating metal and dielectric layers that are parallel to a top surface of the substrate;
forming an upper stack of alternating metal and dielectric layers that are parallel to the top surface of the substrate, the upper stack vertically stacked over the lower stack;
forming a first opening through the upper stack and the lower stack until uncovering a top surface of the substrate; and
forming within the first opening a lower transistor that is insulated from the substrate and an upper transistor that is vertically stacked over the lower transistor,
wherein the lower transistor includes a lower channel that is elongated horizontally and is in-plane with a first lower metal layer of the lower stack,
the lower transistor is electrically connected to a lower metal capacitor that includes the first lower metal layer as a first lower metal plate and a second lower metal layer of the lower stack as a second lower metal plate,
the upper transistor includes an upper channel that is elongated horizontally and is in-plane with a first upper metal layer of the upper stack, and
the upper transistor is electrically connected to an upper metal capacitor that includes the first upper metal layer as a first upper metal plate and a second upper metal layer of the upper stack as a second upper metal plate.

2. The method of claim 1, further comprising:
forming a second opening through the upper stack and the lower stack until uncovering at least a portion of the second lower metal layer of the lower stack;
recessing a portion of the first lower metal layer of the lower stack and the first upper metal layer of the upper stack that is uncovered by the second opening and replacing with an insulating material; and
filing the second opening with a first metal material to electrically connect the second lower metal layer of the lower stack and the second upper metal layer of the upper stack.

3. The method of claim 1, wherein the lower transistor further includes a lower gate region that surrounds the lower channel, and the upper transistor further includes an upper gate region that surrounds the upper channel.

4. The method of claim 3, wherein the upper gate region is electrically connected to the lower gate region.

5. The method of claim 4, wherein the lower transistor and the upper transistor are formed by:
epitaxially growing a first single crystal material on the substrate within the first opening;
epitaxially growing a second single crystal material over the first single crystal material to maintain single crystallinity, the second single crystal material etched selectively with respect to the first single crystal material;
epitaxially growing the lower channel of the lower transistor over the second single crystal material, the lower channel covering a lateral side of the first lower metal layer of the lower stack;
epitaxially growing a third single crystal material over the lower channel, the third single crystal material etched selectively with respect to the first single crystal material;
epitaxially growing the upper channel of the upper transistor over the third single crystal material, the upper channel covering a lateral side of the first upper metal layer of the upper stack;
epitaxially growing a fourth single crystal material over the upper channel, the fourth single crystal material etched selectively with respect to the first single crystal material;
etching and removing the first single crystal material and replacing with an insulating material;
etching the second single crystal material, the third single crystal material and the fourth single crystal material to uncover the lower channel and the upper channel;
forming the lower gate region and the upper gate region that surround the lower channel and the upper channel, respectively; and
filling the first opening with a second metal material.

6. The method of claim 5, further comprising:
recessing within the first opening a portion of a second lower metal layer of the lower stack and a second upper metal layer of the upper stack that are stacked over the first lower metal layer and the first upper metal layer, respectively, and replacing with an insulating material.

7. The method of claim 5, wherein the second single crystal material, the third single crystal material and the fourth single crystal material are a same.

8. The method of claim 7, wherein the second single crystal material includes SiGe30.

9. The method of claim 5, wherein the first single crystal material includes SiGe90.

10. The method of claim 5, further comprising:
annealing the lower channel to develop a first silicide at two ends thereof; and
annealing the upper channel to develop a second silicide at two ends thereof.

11. The method of claim 3, wherein the lower metal capacitor further includes a lower dielectric layer of the lower stack that is between to the first lower metal plate and the second lower metal plate and is in-plane with the lower gate region of the lower transistor, and the upper metal capacitor further includes an upper dielectric layer of the upper stack that is between the first upper metal plate and the second upper metal plate and is in-plane with the upper gate region of the upper transistor.

12. The method of claim 1, wherein the lower transistor is narrower than the lower metal capacitor horizontally.

13. A semiconductor structure, comprising:
a lower transistor including a lower channel that is elongated horizontally;
an upper transistor vertically stacked over the lower transistor and including an upper channel that is elongated horizontally;
a lower metal capacitor electrically connected to and horizontally elongated from the lower transistor, the lower metal capacitor including a first lower metal plate that is in-plane with the lower channel of the lower transistor; and
an upper metal capacitor vertically stacked over the lower metal capacitor and electrically connected to and horizontally elongated from the upper transistor, the upper metal capacitor including a first upper metal plate that is in-plane with the upper channel of the upper transistor.

14. The semiconductor structure of claim 13, wherein the lower metal capacitor further includes a second lower metal plate that is parallel to and insulated from the first lower metal plate, and the upper metal capacitor further includes a second upper metal plate that is parallel to and insulated from the first upper metal plate.

15. The semiconductor structure of claim 14, wherein the second upper metal plate is electrically connected to the second lower metal plate.

16. The semiconductor structure of claim 13, wherein the lower transistor further includes a lower gate region that surrounds the lower channel and the upper transistor further includes an upper gate region that surrounds the upper channel.

17. The semiconductor structure of claim 16, wherein the upper gate region is electrically connected to the lower gate region.

18. The semiconductor structure of claim 16, wherein the lower metal capacitor further includes a lower dielectric layer that is parallel to the first lower metal plate and in-plane with the lower gate region of the lower transistor, and the upper metal capacitor further includes an upper dielectric layer that is parallel to the first upper metal plate and in-plane with the upper gate region of the upper transistor.

19. The semiconductor structure of claim 13, wherein the lower transistor is narrower than the lower metal capacitor horizontally.

20. The semiconductor structure of claim 13, further comprising:
a first silicide formed on two ends of the lower channel of the lower transistor; and
a second silicide formed on two ends of the upper channel of the upper transistor.
